(19) United States
(12) Patent Application Publication
(10) Pub. No.: US 2021/0367103 A1
(43) Pub. Date: Nov. 25, 2021

(54) MICRO LIGHT EMITTING DIODE

(71) Applicant: PlayNitride Display Co., Ltd., MiaoLi County (TW)

(72) Inventors: Yi-Chun Shih, MiaoLi County (TW); Pei-Hsin Chen, MiaoLi County (TW); Yi-Ching Chen, MiaoLi County (TW)

(73) Assignee: PlayNitride Display Co., Ltd., MiaoLi County (TW)

(21) Appl. No.: 16/996,925

(22) Filed: Aug. 19, 2020

(30) Foreign Application Priority Data
May 21, 2020 (TW) 109116828

(51) Int. Cl. H01L 33/22; H01L 33/38

(52) U.S. Cl. CPC H01L 33/22; H01L 33/38

(57) ABSTRACT

A micro light emitting diode includes an epitaxial structure, a first electrode, and a second electrode. The epitaxial structure has a surface. The first electrode and the second electrode are respectively disposed on the surface of the epitaxial structure. The second electrode is located outside the first electrode, and the second electrode is symmetrically disposed with respect to a geometric center of the epitaxial structure.

### CROSS-REFERENCE TO RELATED APPLICATION

This application claims the priority benefit of Taiwan application serial no. 109116828, filed on May 21, 2020. The entirety of the above-mentioned patent application is hereby incorporated by reference herein and made a part of this specification.

### BACKGROUND

### Technical Field

The disclosure relates to a light emitting structure, and in particular, to a micro light emitting diode.

### Description of Related Art

A micro light emitting diode display device may feature advantages such as low power consumption, high brightness, high color saturation, fast response, and power saving. Moreover, a micro light emitting diode display device may further provide advantages such as good material stability and no image sticking. Accordingly, development on the display technology of the micro light emitting diode display devices has received much attention.

As far as the process is concerned, when a micro light emitting diode is transferred from a growth substrate to a driver circuit substrate, the micro light emitting diode is required to be heated and pressured, so that the micro light emitting diode may be electrically bonded to the driver circuit substrate. Nevertheless, in an existing micro light emitting diode, the N electrode is electrically connected to the N-type semiconductor layer through the design of vias. As such, the P electrode and the N electrode, which are located at the same side of the epitaxial structure and located at the left and right sides, are not evenly pressured. In addition, during transferring, time is required to be spent on accurately aligning the P electrode and the N electrode onto the connection pad of the driver circuit substrate. Therefore, how to allow the electrodes of a micro light emitting diode to be evenly pressured and rapidly aligned during transferring and bonding is an important issue.

### SUMMARY

The disclosure provides a micro light emitting diode in which electrodes are not required to be precisely aligned and may be evenly pressured in subsequent transferring and bonding procedures and exhibiting favorable structural reliability.

A micro light emitting diode provided by the disclosure includes an epitaxial structure, a first electrode, and a second electrode. The epitaxial structure has a surface. The first electrode is disposed on the surface of the epitaxial structure. The second electrode is disposed on the surface of the epitaxial structure. The second electrode is located outside the first electrode, and the second electrode is symmetrically disposed with respect to a geometric center of the epitaxial structure.

In an embodiment of the disclosure, the epitaxial structure includes a first-type semiconductor layer, a light emitting layer, a second-type semiconductor layer, and at least one via. The light emitting layer is located between the first-type semiconductor layer and the second-type semiconductor layer, and the at least one via extends from the second-type semiconductor layer to the first-type semiconductor layer. The micro light emitting diode further includes an insulating layer and a conductive material. The insulating layer and the first electrode are disposed on the second-type semiconductor layer and extends to cover an inner wall of the at least one via. The conductive material fills the at least one via and is located between the second electrode and the insulating layer.

In an embodiment of the disclosure, in a top view, a ratio of an area of the at least one via to an area of the second electrode is smaller than or equal to 0.5.

In an embodiment of the disclosure, the at least one via includes two vias located at two opposite sides of the first electrode. The two vias are symmetrically disposed with respect to the geometric center of the epitaxial structure.

In an embodiment of the disclosure, in a top view, an area of the second electrode is greater than an area of the first electrode.

In an embodiment of the disclosure, the second electrode is point-symmetric with respect to the geometric center of the epitaxial structure, or the second electrode is line-symmetric with respect to a line of symmetry of the geometric center.

In an embodiment of the disclosure, a minimum gap is provided between the second electrode and the first electrode, and the minimum gap is greater than or equal to 0.5 microns.

In an embodiment of the disclosure, the first electrode has a first maximum width, the second electrode has a second maximum width, and the second maximum width is smaller than or equal to the first maximum width.

In an embodiment of the disclosure, the first electrode is symmetrically disposed with respect to the geometric center of the epitaxial structure.

In an embodiment of the disclosure, the first electrode and the second electrode are not coplanar.

In an embodiment of the disclosure, a first surface of the first electrode is higher than a second surface of the second electrode.

In an embodiment of the disclosure, a Young's modulus of the first electrode is smaller than a Young's modulus of the second electrode.

In an embodiment of the disclosure, a first surface of the first electrode is lower than a second surface of the second electrode.

In an embodiment of the disclosure, a Young's modulus of the first electrode is greater than a Young's modulus of the second electrode.

In an embodiment of the disclosure, a width of the second electrode is smaller than a distance between the second electrode and the first electrode.

In an embodiment of the disclosure, in a top view, a shape of the epitaxial structure and a shape of the second electrode are conformal, and the second electrode is a ring electrode.

In an embodiment of the disclosure, an interval distance is provided between the second electrode and a surrounding surface of the epitaxial structure, and the interval distance is smaller than or equal to 5 microns and is greater than or equal to 0.5 microns.

In an embodiment of the disclosure, a ratio of a side length of the second electrode to a total side length of the epitaxial structure is greater than or equal to 0.2. A ratio of an area of the second electrode to a total surface area of the epitaxial structure is greater than or equal to 0.2 and is smaller than or equal to 0.8.

In an embodiment of the disclosure, the second electrode has a first electrical property and a second electrical property, the first electrical property is different from the second electrical property, and the second electrical property is identical to an electrical property of the first electrode.

In an embodiment of the disclosure, the first electrode includes a plurality of point electrodes, and the second electrode includes a plurality of linear electrodes.

In an embodiment of the disclosure, the second electrode includes a plurality of electrode portions and a plurality of trace portions, and the electrode portions are respectively connected to the trace portions.

In an embodiment of the disclosure, a material of the electrode portions is different from a material of the trace portions.

In an embodiment of the disclosure, the first electrode includes an electrode portion and a plurality of trace portions, and the trace portions are connected to the electrode portion.

In an embodiment of the disclosure, a material of the electrode portions is different from a material of the trace portions.

A micro light emitting diode provided by the disclosure includes an epitaxial structure, a first electrode, and a second electrode. The first electrode is disposed on the surface of the epitaxial structure. The second electrode is disposed on the surface of the epitaxial structure.

The second electrode is located outside the first electrode, and the second electrode is symmetrically disposed with respect to a geometric center of the first electrode.

To sum up, in the design of the micro light emitting diode provided by the disclosure, since the second electrode located outside the first electrode is symmetrically disposed with respect to the geometric center of the epitaxial structure, in the subsequent transferring and bonding procedures, the first electrode and the second electrode are not required to be precisely aligned and are evenly pressured. In this way, the micro light emitting diode provided by the disclosure may exhibit favorable structural reliability.

To make the aforementioned features and advantages more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic top view of a micro light emitting diode according to an embodiment of the disclosure.

FIG. 1B is a schematic cross-sectional view taken long a line A-A in FIG. 1A.

FIG. 2A is a schematic top view of a micro light emitting diode according to another embodiment of the disclosure.

FIG. 2B is a schematic cross-sectional view taken long a line B-B in FIG. 2A.

FIG. 3A is a schematic cross-sectional view of a micro light emitting diode according to another embodiment of the disclosure.

FIG. 3B is a schematic cross-sectional view of a micro light emitting diode according to another embodiment of the disclosure.

FIG. 4A is a schematic top view of a micro light emitting diode according to another embodiment of the disclosure.

FIG. 4B is a schematic top view of a micro light emitting diode according to another embodiment of the disclosure.

FIG. 5A is a schematic top view of a micro light emitting diode according to another embodiment of the disclosure.

FIG. 5B is a schematic top view of a micro light emitting diode according to another embodiment of the disclosure.

FIG. 6A is a schematic top view of a micro light emitting diode according to another embodiment of the disclosure.

FIG. 6B is a schematic top view of a micro light emitting diode according to another embodiment of the disclosure.

FIG. 7A is a schematic top view of a micro light emitting diode according to another embodiment of the disclosure.

FIG. 7B is a schematic top view of a micro light emitting diode according to another embodiment of the disclosure.

FIG. 7C is a schematic top view of a micro light emitting diode according to another embodiment of the disclosure.

FIG. 8 is a schematic cross-sectional view of a micro light emitting diode display device according to another embodiment of the disclosure.

### DESCRIPTION OF THE EMBODIMENTS

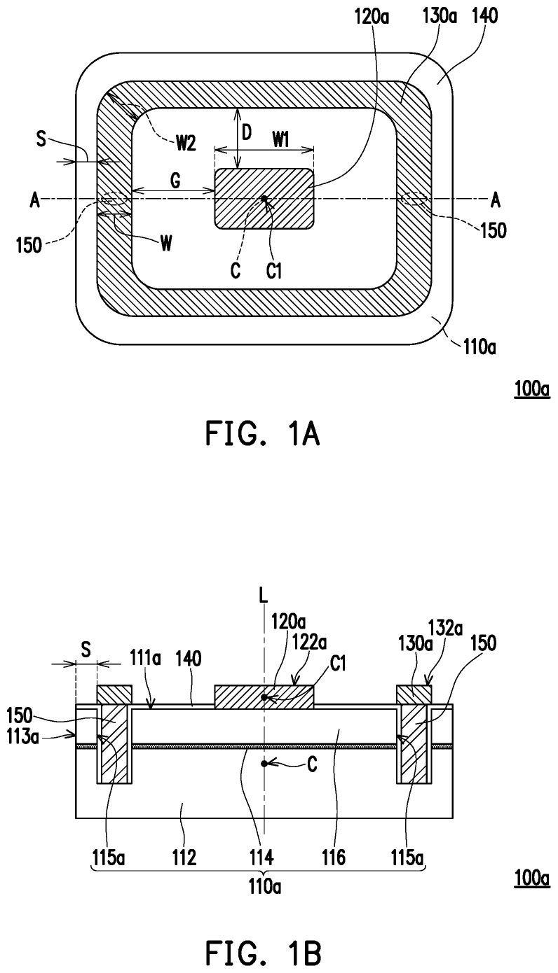

FIG. 1A is a schematic top view of a micro light emitting diode according to an embodiment of the disclosure. FIG. 1B is a schematic cross-sectional view taken long a line A-A in FIG. 1A. With reference to FIG. 1A and FIG. 1B together, in this embodiment, a micro light emitting diode 100a includes an epitaxial structure 110a, a first electrode 120a, and a second electrode 130a. The epitaxial structure 110a has a surface 111a. The first electrode 120a and the second electrode 130a are respectively disposed on the surface 111a of the epitaxial structure 110a. The second electrode 130a is located outside the first electrode 120a, and the second electrode 120a is symmetrically disposed with respect to a geometric center C of the epitaxial structure 110a.

To be specific, the epitaxial structure 110a of this embodiment includes a first-type semiconductor layer 112, a light emitting layer 114, a second-type semiconductor layer 116, and at least one via 115a (two vias 115a are schematically illustrated). The light-emitting layer 114 is located between the first-type semiconductor layer 112 and the second-type semiconductor layer 116, and the vias 115a extend from the second-type semiconductor layer 116 to the first-type semiconductor layer 112. Herein, the two vias 115a are located at two opposite sides of the first electrode 120a, and the two vias 115a are symmetrically disposed with respect to the geometric center C of the epitaxial structure 110a. Moreover, the micro light emitting diode 100a provided by this embodiment further includes an insulating layer 140 and a conductive material 150. The insulating layer 140 and the first electrode 120a are disposed on the second-type semiconductor layer 116 and extends to cover the inner walls of the vias 115a. The conductive material 150 fills the vias 115a and is located between the second electrode 130a and the insulating layer 140. The insulating layer 140 may electrically insulate the second electrode 130a from the second-type semiconductor layer 116. Herein, the first electrode 120a is electrically connected to the second-type semiconductor layer 116, and the second electrode 130a is electrically connected to the first-type semiconductor layer 112 through the conductive material 150. In an embodiment that is not shown, an air gap may be provided between the conductive material 150 and the second electrode 130a, so that the conductive material 150 may partially contact the second electrode 130a, the air gap may act as a buffering space during transfer, and electrical connection may also be performed. The second electrode 130a and the conductive material 150 may be made of different materials. Further, an electrical resistivity of the conductive material 150 is smaller than that of the second electrode 130a, and in this way, an ohmic contact between the conductive material 150 and the first-type semiconductor layer 112 is enhanced. Nevertheless, the second electrode 130a and the conductive material 150 may be made of the same material, and the second electrode 130a and the conductive material 150 is integrally formed and manufactured in a same process, so that a process speed may be increased.

Further, with reference to FIG. 1A again, in a top view, a shape of the epitaxial structure 110a and a shape of the second electrode 130a are conformal, so that a pressure may be evenly applied during bonding. A shape of the first electrode 120a is different from the shape of the second electrode 130a. The second electrode 130a is, for example, a closed ring electrode, and the first electrode 120a is, for example, a block electrode. Herein, the second electrode 130a is implemented as a rectangular ring electrode and surrounds the first electrode 120a. The first electrode 120a may be treated as an inner electrode, and the second electrode 130a may be treated as an outer electrode. A ratio of a side length of the second electrode 130a to a total side length of the epitaxial structure 110a is greater than or equal to 0.2. If the above ratio is smaller than 0.2, a current may not be evenly distributed. Further, a ratio of an area of the second electrode 130a to a total surface area of the epitaxial structure 110a is greater than or equal to 0.2 and is smaller than or equal to 0.8. If the above ratio is excessively small, the epitaxial structure 110a and the second electrode 120a may not be uniformly distributed, and that a current may not be evenly distributed. In an embodiment, one of the first electrode 120a and the second electrode 130a is a P electrode, and the other one of the first electrode 120a and the second electrode 130a is a N electrode. Preferably, the first electrode 120a is the N electrode, and the second electrode 130a is the P electrode. In this way, the epitaxial structure 110a may exhibit a large light emitting area and favorable light output efficiency, but the disclosure is not limited thereto.

Further, in a top view, the area of the second electrode 130a is greater than an area of the first electrode 120a, and the second electrode 130a may act as a reflection layer. Preferably, a ratio of areas of the two vias 115a to the area of the second electrode 130a is smaller than or equal to 0.5. If the above ratio is excessively large, structural strength of the epitaxial structure 110a may be decreased. Preferably, the ratio may be smaller than or equal to 0.3 and may be greater than or equal to 0.05, and within this range, the structural strength of the epitaxial structure 110a and electrical connection efficiency of the second electrode 130a and the first-type semiconductor layer 112 may both be satisfied. The first electrode 120a may be equidistant or may not be equidistant from the second electrode 130a. A minimum gap D is provided between the second electrode 130a and the first electrode 120a, the minimum gap D is greater than or equal to 0.5 microns and is smaller than or equal to 10 microns, and a current may be evenly distributed in this way. The first electrode 120a may exhibit an equal width or an unequal width and has a first maximum width W1, and the second electrode 130a may exhibit an equal width or an unequal width and has a second maximum width W2. The second maximum width W2 is smaller than or equal to the first maximum width W1. In addition, any width W of the second electrode 130a is smaller than a distance G between the second electrode 130a and the first electrode 120a, and a short is prevented from being generated in this way during a transferring and bonding procedure. Moreover, with reference to FIG. 1A and FIG. 1B together, an interval distance S is provided between the second electrode 130a and a surrounding surface 113a of the epitaxial structure 110a, and the interval distance S is smaller than or equal to 5 microns and is greater than or equal to 0.5 microns, so that overflowing is prevented from occurring in the subsequent transferring and bonding procedure.

As shown in FIG. 1B, in this embodiment, the first electrode 120a and the second electrode 130a are coplanar. That is, a first surface 122a of the first electrode 120a is flush with a second surface 132a of the second electrode 130a. Further, the second electrode 130a of this embodiment may be symmetrically disposed with respect to the geometric center C of the epitaxial structure 110a. The geometric center C herein is a geometric center of the epitaxial structure 110a when being viewed from the top. In other embodiments, the surface 111a of the epitaxial structure 110a may also be viewed from the top to obtain a geometric center of the surface 111a, as long as the second electrode 130a and the first electrode 120a are symmetrically disposed with respect to the epitaxial structure 110a. From another perspective, the second electrode 130a is line-symmetric with respect to a line of symmetry L of the geometric center C of the epitaxial structure 110a. Alternatively, the second electrode 130a is symmetric with respect to the line of symmetry L of the geometric center C of the epitaxial structure 110a by 180 degrees. In addition, the second electrode 130a is symmetrically disposed with respect to the first electrode 120a, and the first electrode 120a is symmetrically disposed with respect to the geometric center C of the epitaxial structure 110a. In this embodiment, the second electrode 130a is also symmetrically disposed with respect to the geometric center C1 of the first electrode 120a.

In short, since the second electrode 130a located outside the first electrode 120a and surrounding the first electrode 120a is symmetrically disposed with respect to the geometric center C of the epitaxial structure 110a, in the subsequent transferring and bonding procedures, the first electrode 120a and the second electrode 130a are not required to be precisely aligned and may be evenly pressured. In this way, the micro light emitting diode 100a provided by this embodiment may exhibit favorable structural reliability and an increased process margin.

It should be noted that the reference numerals and a part of the contents in the previous embodiment are used in the following embodiments, in which identical reference numerals indicate identical or similar components, and repeated description of the same technical contents is omitted. Please refer to the descriptions of the previous embodiment for the omitted contents, which will not be repeated hereinafter.

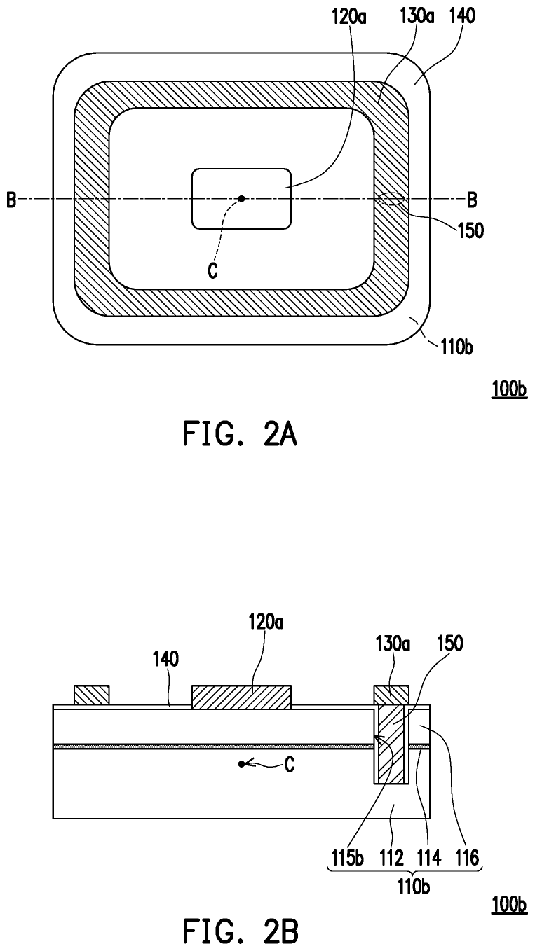

FIG. 2A is a schematic top view of a micro light emitting diode according to another embodiment of the disclosure. FIG. 2B is a schematic cross-sectional view taken long a line B-B in FIG. 2A. With reference to FIG. 1B, FIG. 2A, and FIG. 2B together, a micro light emitting diode 100b provided by this embodiment is similar to the micro light emitting diode 100a in FIG. 1B, and a difference therebetween lies in that: an epitaxial structure 110b of this embodiment has only one via 115b. An inner structure of the epitaxial structure 110b is thus prevented from being damaged by vias, and the micro light emitting diode 100b provided by this embodiment accordingly has a large light output area. The second electrode 130a has a ring shape and conforms to an edge of the epitaxial structure 110b. As such, weights of left and right sides of the epitaxial structure 110b are balanced, and a pressure may thus be evenly applied to the micro light emitting diode 100b in the transferring and bonding procedures.

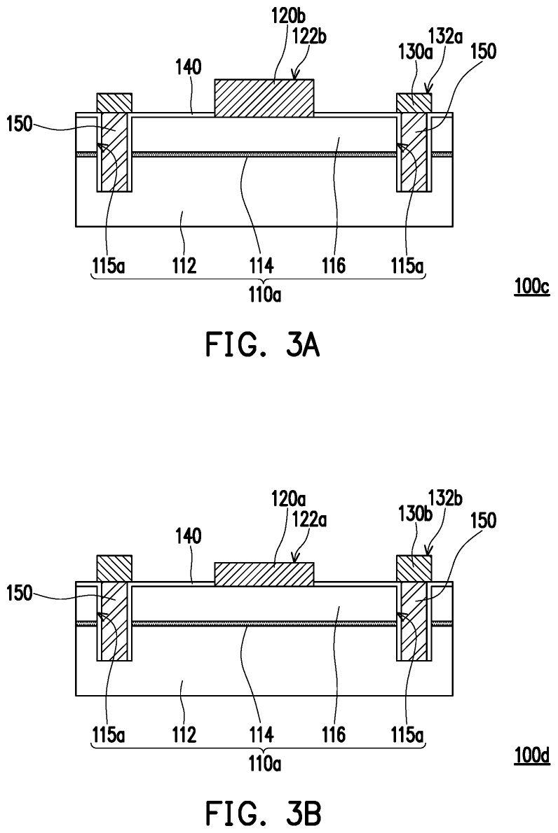

FIG. 3A is a schematic cross-sectional view of a micro light emitting diode according to another embodiment of the disclosure. With reference to FIG. 3A and FIG. 1B together, a micro light emitting diode 100c provided by this embodiment is similar to the micro light emitting diode 100a in FIG. 1B, and a difference therebetween lies in that: a first electrode 120b and the second electrode 130a are not coplanar in this embodiment. To be specific, a first surface 122b of the first electrode 120b is higher than the second surface 132a of the second electrode 130a, and a Young's modulus of the first electrode 120b is smaller than a Young's modulus of the second electrode 130a. Therefore, the first electrode 120b may act as a buffer during transferring, so that a pressure applied by a transfer head (not shown) to a center may be reduced during transferring.

FIG. 3B is a schematic cross-sectional view of a micro light emitting diode according to another embodiment of the disclosure. With reference to FIG. 3B and FIG. 1B together, a micro light emitting diode 100d provided by this embodiment is similar to the micro light emitting diode 100a in FIG. 1B, and a difference therebetween lies in that: the first electrode 120a and a second electrode 130b are not coplanar in this embodiment. To be specific, the first surface 122a of the first electrode 120a is lower than the second surface 132a of the second electrode 130b, and a Young's modulus of the first electrode 120a is greater than a Young's modulus of the second electrode 130b. Therefore, the second electrode 130b located outside may act as a buffer during transfer, so that accuracy of alignment performed by the transfer head (not shown) may be improved during transfer.

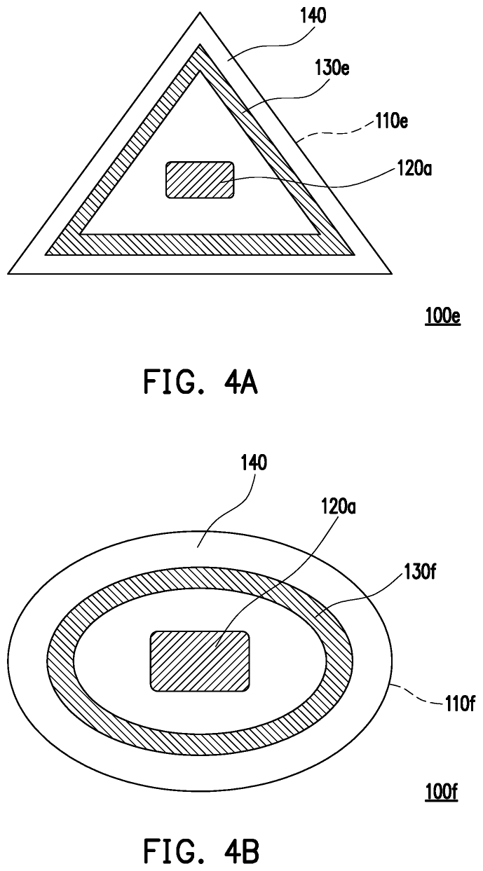

FIG. 4A is a schematic top view of a micro light emitting diode according to another embodiment of the disclosure. With reference to FIG. 4A and FIG. 1A together, a micro light emitting diode 100e provided by this embodiment is similar to the micro light emitting diode 100a in FIG. 1B, and a difference therebetween lies in that: in this embodiment, a shape of an epitaxial structure 110e and a shape of a second electrode 130e are conformal, and the second electrode 130e is implemented as a triangular ring electrode and surrounds the first electrode 120a.

FIG. 4B is a schematic top view of a micro light emitting diode according to another embodiment of the disclosure. With reference to FIG. 4B and FIG. 1A together, a micro light emitting diode 100f provided by this embodiment is similar to the micro light emitting diode 100a in FIG. 1B, and a difference therebetween lies in that: in this embodiment, a shape of an epitaxial structure 110f and a shape of a second electrode 130f are conformal, and the second electrode 130f is implemented as an elliptical ring electrode and surrounds the first electrode 120a.

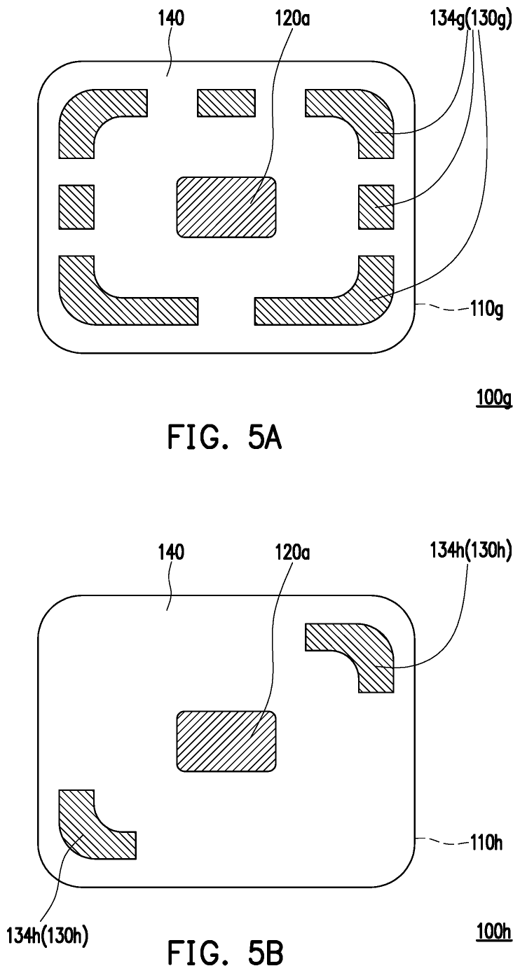

FIG. 5A is a schematic top view of a micro light emitting diode according to another embodiment of the disclosure. With reference to FIG. 5A and FIG. 1A together, a micro light emitting diode 100g provided by this embodiment is similar to the micro light emitting diode 100a in FIG. 1B, and a difference therebetween lies in that: a second electrode 130g provided by this embodiment is an open ring electrode. Further, the second electrode 130g includes a plurality of electrode portions 134g separated from one another, and the electrode portions 134g are arranged along a top-view shape of the epitaxial structure 110g and surround the first electrode 120a Through theses separated electrode portions 134g, good alignment accuracy during transferring may be provided. Moreover, when pressuring and heating are performed during transferring, overflowing to other positions may be prevented from occurring thanks to buffering provided by the second electrode 130g.

FIG. 5B is a schematic top view of a micro light emitting diode according to another embodiment of the disclosure. With reference to FIG. 5B and FIG. 5A together, a micro light emitting diode 100h provided by this embodiment is similar to the micro light emitting diode 100g in FIG. 5A, and a difference therebetween lies in that: a second electrode 130h provided by this embodiment has only two electrode portions 134h located on a diagonal line of an epitaxial structure 110h. In this way, good alignment accuracy during transferring is provided, light shading is prevented during light output at an electrode side, and light output efficiency may also be enhanced.

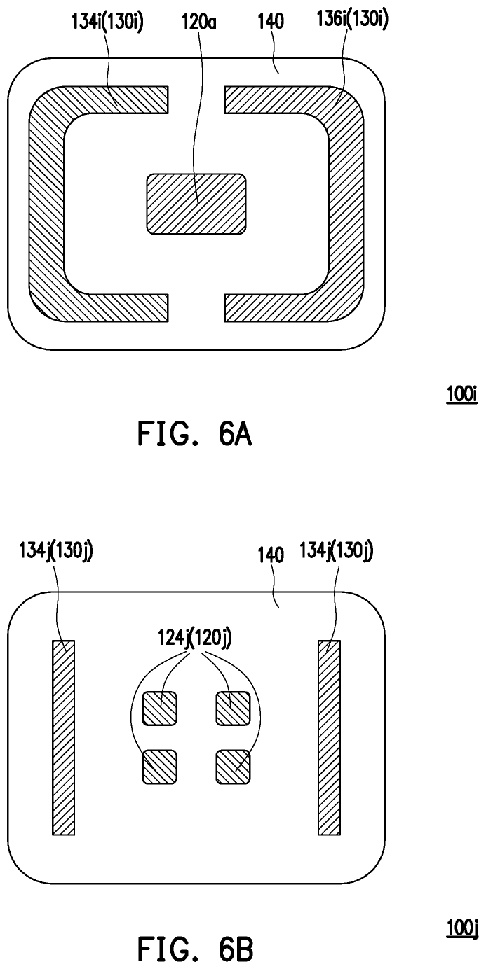

FIG. 6A is a schematic top view of a micro light emitting diode according to another embodiment of the disclosure. With reference to FIG. 6A and FIG. 5A together, a micro light emitting diode 100i provided by this embodiment is similar to the micro light emitting diode 100g in FIG. 5A, and a difference therebetween lies in that: a second electrode 130i provided by this embodiment includes a first electrode portion 134i and a second electrode portion 136i separated from each other. The first electrode portion 134i has a first electrical property, the second electrode portion 136i has a second electrical property, and the first electrical property is different from the second electrical property. In particular, the second electrical property of the second electrode portion 136i is identical to an electrical property of the first electrode 120a. In short, the second electrode 130i is formed by two different electrical properties. As the second electrode 130i is formed by two different electrical properties and is designed to be symmetrically disposed, good alignment accuracy during transferring may be provided, and different configuration areas may be provided for different electrical properties of an electrode according to needs, so that a current may be evenly distributed.

FIG. 6B is a schematic top view of a micro light emitting diode according to another embodiment of the disclosure. With reference to FIG. 6B and FIG. 1A together, a micro light emitting diode 100j provided by this embodiment is similar to the micro light emitting diode 100a in FIG. 1A, and a difference therebetween lies in that: in this embodiment, a first electrode 120j includes a plurality of point electrodes 124j (four point electrodes 124j are schematically shown), and a second electrode 130j includes a plurality of linear electrodes 134j (two linear electrodes 134j are schematically shown). The point electrodes 124j are separated from one another and are rectangular block electrodes, and the linear electrodes 134j are located at two opposite sides of the point electrodes 124j and are rectangular strip electrodes. In this way, electrode uniformity is enhanced and light shading at a center is prevented from occurring.

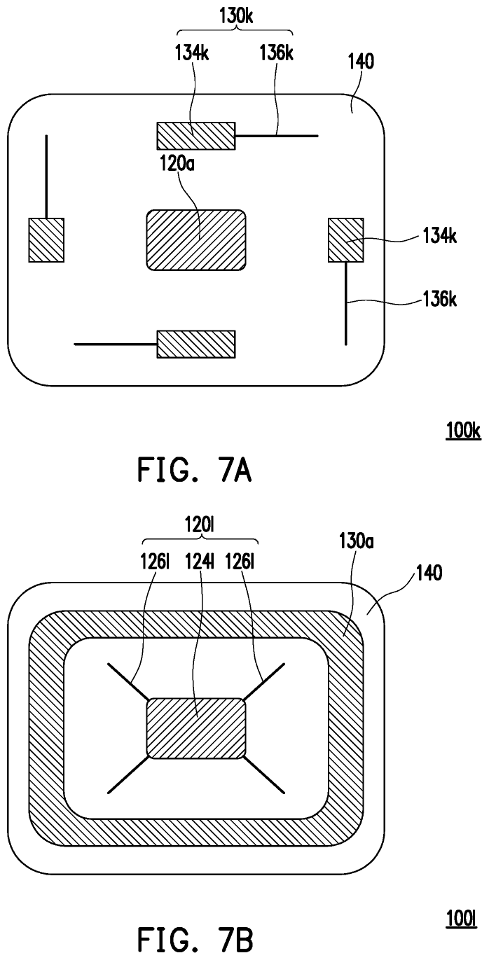

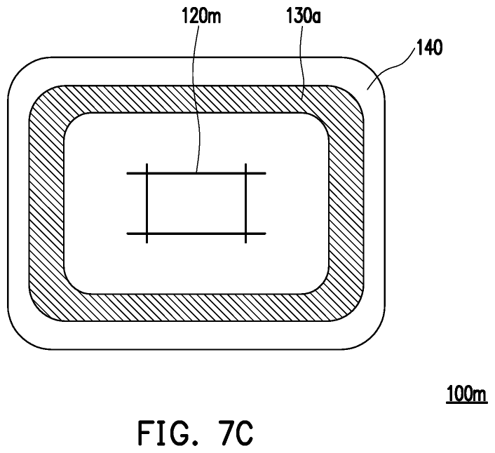

FIG. 7A is a schematic top view of a micro light emitting diode according to another embodiment of the disclosure. With reference to FIG. 7A and FIG. 1A together, a micro light emitting diode 100k provided by this embodiment is similar to the micro light emitting diode 100a in FIG. 1A, and a difference therebetween lies in that: a second electrode 130k provided by this embodiment includes a plurality of electrode portions 134k and a plurality of trace portions 136k, and the electrode portions 134k are respectively connected to the trace portions 136k. Herein, a material of the electrode portions 134k is different from a material of the trace portions 136k, and an electrical resistance of a trace portion 136k is smaller than an electrical resistance of an electrode portion 134k, so that electrical connection efficiency may be improved. Herein, the material of the electrode portions 134k is, for example, a transparent conductive material, and the material of the trace portions 136k is, for example, metal. In another embodiment, the electrode portions 134k and the trace portions 136k are made of the same material or are integrally formed, which still belongs to the protection scope of the disclosure.

FIG. 7B is a schematic top view of a micro light emitting diode according to another embodiment of the disclosure. With reference to FIG. 7B and FIG. 1A together, a micro light emitting diode 100l provided by this embodiment is similar to the micro light emitting diode 100a in FIG. 1A, and a difference therebetween lies in that: a first electrode 120l provided by this disclosure includes an electrode portion 124l and a plurality of trace portions 126l, and the trace portions 126l are connected to the electrode portion 124l. Herein, a material of the electrode portion 124l is different from a material of the trace portions 126l, and an electrical resistance of a trace portion 126l is smaller than an electrical resistance of the electrode portion 124l, so that electrical connection efficiency may be improved. Herein, the material of the electrode portion 124l is, for example, a transparent conductive material, and the material of the trace portions 126l is, for example, metal. In another embodiment, the electrode portion 124l and the trace portions 126l are made of the same material or are integrally formed, which still belongs to the protection scope of the disclosure.

FIG. 7C is a schematic top view of a micro light emitting diode according to another embodiment of the disclosure. With reference to FIG. 7C and FIG. 1A together, a micro light emitting diode 100m provided by this embodiment is similar to the micro light emitting diode 100a in FIG. 1A, and a difference therebetween lies in that: a first electrode 120m provided by this embodiment is implemented as a mesh electrode. In this way, the first electrode 120m whose center is applied by a pressure may have an increased buffering space, so that overflowing to the second electrode 130a may be prevented from occurring.

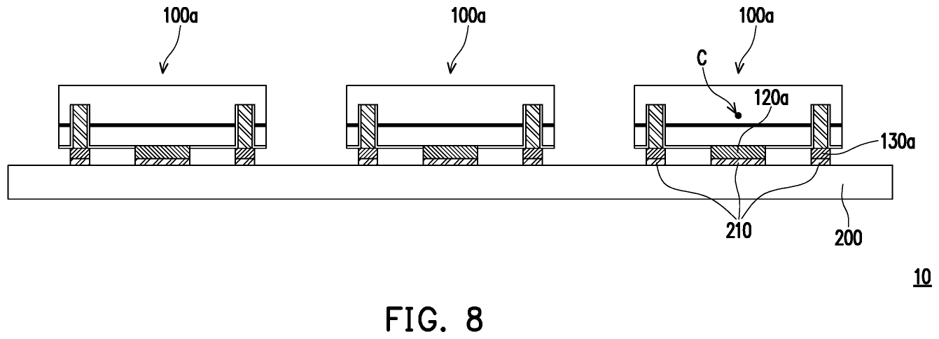

FIG. 8 is a schematic cross-sectional view of a micro light emitting diode display device according to another embodiment of the disclosure. With reference to FIG. 8, in applications, a plurality of micro light emitting diodes 100a in FIG. 1B may be transferred and bonded onto a connection pad 210 of a driver substrate 200 to form a micro light emitting diode display device 10. To be specific, the first electrode 120a and the second electrode 130a surrounding the first electrode 120a of each micro light emitting diode 100a are not required to be precisely aligned and may be easily bonded onto the connection pad 210 of the driver substrate 200. In addition, since the second electrode 130a is symmetrically disposed with respect to the geometric center C of the epitaxial structure 110a, during the transferring and bonding procedures, a pressure may be evenly applied to the first electrode 120a and the second electrode 130a.

In view of the foregoing, in the design of the micro light emitting diode provided by the disclosure, since the second electrode located outside the first electrode is symmetrically disposed with respect to the geometric center of the epitaxial structure, in the subsequent transferring and bonding procedures, the first electrode and the second electrode are not required to be precisely aligned and are evenly pressured. In this way, the micro light emitting diode provided by the disclosure may exhibit favorable structural reliability.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A micro light emitting diode, comprising:
an epitaxial structure, having a surface;
a first electrode, disposed on the surface of the epitaxial structure; and
a second electrode, disposed on the surface of the epitaxial structure, wherein the second electrode is located outside the first electrode, and the second electrode is symmetrically disposed with respect to a geometric center of the epitaxial structure.

2. The micro light emitting diode according to claim 1, wherein the epitaxial structure comprises a first-type semiconductor layer, a light emitting layer, a second-type semiconductor layer, and at least one via, the light emitting layer is located between the first-type semiconductor layer and the second-type semiconductor layer, the at least one via extends from the second-type semiconductor layer to the first-type semiconductor layer, and the micro light emitting diode further comprises:
an insulating layer, disposed on the second-type semiconductor layer together with the first electrode, wherein the insulating layer extends to cover an inner wall of the at least one via; and
a conductive material, filling the at least one via, located between the second electrode and the insulating layer.

3. The micro light emitting diode according to claim 2, wherein in a top view, a ratio of an area of the at least one via to an area of the second electrode is smaller than or equal to 0.5.

4. The micro light emitting diode according to claim 2, wherein the at least one via comprises two vias located at two opposite sides of the first electrode, and the two vias are symmetrically disposed with respect to the geometric center of the epitaxial structure.

5. The micro light emitting diode according to claim 1, wherein in a top view, an area of the second electrode is greater than an area of the first electrode.

6. The micro light emitting diode according to claim 1, wherein the second electrode is point-symmetric with respect to the geometric center of the epitaxial structure, or the second electrode is line-symmetric with respect to a line of symmetry of the geometric center.

7. The micro light emitting diode according to claim 1, wherein a minimum gap is provided between the second electrode and the first electrode, and the minimum gap is greater than or equal to 0.5 microns and is smaller than or equal to 10 microns.

8. The micro light emitting diode according to claim 1, wherein the first electrode has a first maximum width, the second electrode has a second maximum width, and the second maximum width is smaller than or equal to the first maximum width.

9. The micro light emitting diode according to claim 1, wherein the first electrode is symmetrically disposed with respect to the geometric center of the epitaxial structure.

10. The micro light emitting diode according to claim 1, wherein the first electrode and the second electrode are not coplanar.

11. The micro light emitting diode according to claim 10, wherein a first surface of the first electrode is higher than a second surface of the second electrode.

12. The micro light emitting diode according to claim 11, wherein a Young's modulus of the first electrode is smaller than a Young's modulus of the second electrode.

13. The micro light emitting diode according to claim 10, wherein a first surface of the first electrode is lower than a second surface of the second electrode.

14. The micro light emitting diode according to claim 13, wherein a Young's modulus of the first electrode is greater than a Young's modulus of the second electrode.

15. The micro light emitting diode according to claim 1, wherein a width of the second electrode is smaller than a distance between the second electrode and the first electrode.

16. The micro light emitting diode according to claim 1, wherein in a top view, a shape of the epitaxial structure and a shape of the second electrode are conformal, and the second electrode is a ring electrode.

17. The micro light emitting diode according to claim 1, wherein an interval distance is provided between the second electrode and a surrounding surface of the epitaxial structure, and the interval distance is smaller than or equal to 5 microns and is greater than or equal to 0.5 microns.

18. The micro light emitting diode according to claim 1, wherein a ratio of a side length of the second electrode to a total side length of the epitaxial structure is greater than or equal to 0.2, and a ratio of an area of the second electrode to a total surface area of the epitaxial structure is greater than or equal to 0.2 and is smaller than or equal to 0.8.

19. The micro light emitting diode according to claim 1, wherein the second electrode has a first electrical property and a second electrical property, the first electrical property is different from the second electrical property, and the second electrical property is identical to an electrical property of the first electrode.

20. The micro light emitting diode according to claim 1, wherein the first electrode comprises a plurality of point electrodes, and the second electrode comprises a plurality of linear electrodes.

21. The micro light emitting diode according to claim 1, wherein the second electrode comprises a plurality of electrode portions and a plurality of trace portions, and the electrode portions are respectively connected to the trace portions.

22. The micro light emitting diode according to claim 21, wherein a material of the electrode portions is different from a material of the trace portions.

23. The micro light emitting diode according to claim 1, wherein the first electrode comprises an electrode portion and a plurality of trace portions, and the trace portions are connected to the electrode portion.

24. The micro light emitting diode according to claim 23, wherein a material of the electrode portion is different from a material of the trace portions.

25. A micro light emitting diode, comprising:
an epitaxial structure, having a surface;
a first electrode, disposed on the surface of the epitaxial structure; and
a second electrode, disposed on the surface of the epitaxial structure, wherein the second electrode is located outside the first electrode, and the second electrode is symmetrically disposed with respect to a geometric center of the first electrode.
